(19) United States
(12) Patent Application Publication
(10) Pub. No.: US 2017/0077357 A1
(43) Pub. Date: Mar. 16, 2017

(54) FLEXIBLE CIRCUIT ON REFLECTIVE SUBSTRATE

(71) Applicant: 3M INNOVATIVE PROPERTIES COMPANY, St. Paul, MN (US)

(72) Inventor: Michael A. Meis, Stillwater, MN (US)

(21) Appl. No.: 15/124,513

(22) PCT Filed: Apr. 2, 2015
(86) PCT No.: PCT/US15/24052

§ 371 Date: Sep. 8, 2016

Related U.S. Application Data
(60) Provisional application No. 61/993,390, filed on May 15, 2014.

(51) Int. Cl. H01L 33/46; H01L 33/00

(52) U.S. Cl. CPC H01L 33/46; H01L 33/005; H01L 2933/0025

(57) ABSTRACT

The present disclosure describes materials and methods for creating electrical circuits on a non-conductive multilayer reflector substrate that can withstand reflow temperatures with low temperature solder pastes without creating distortions in the reflective substrate. The materials and methods include the use of a novel reflective mirror film based on silicone polyoxamide polymers or copolymers, which can retain reflectivity at these temperatures without damage to reflection or other film properties.

### BACKGROUND

In many lighting applications it is desirable to combine LEDs with a reflective surface, in order to create high efficiency light sources. While typical circuit boards having mounted LEDs can be coated with reflective materials such as white ink, epoxy, or paint, these surfaces typically only have reflectivity values in the 70% to 90% range. In addition, these types of surfaces generally are diffusely reflective, and scattering light may actually decrease efficiency in some lighting systems. A specularly reflective surface such as a metal can help direct reflected light in a complimentary direction and thereby increase efficiency. However, applying a reflective metallic coating to the surface of a circuit board can be problematic, as the metal can short out circuit board conductors.

### SUMMARY

The present disclosure describes materials and methods for creating electrical circuits on a non-conductive multilayer reflector substrate that can withstand reflow temperatures with low temperature solder pastes without creating distortions in the reflective substrate. The materials and methods include the use of a novel reflective mirror film based on silicone polyoxamide polymers or copolymers, which can retain reflectivity at these temperatures without damage to reflection or other film properties. In one aspect, the present disclosure provides for a flexible circuit that includes a visible-light reflective film having alternating layers of a first polymeric material and a second polymeric material, each having a different index of refraction, and where at least one of the first and second polymeric materials includes a polydiorganosiloxane polyoxamide block copolymer; and an electrically conductive metal disposed in a circuit pattern on the visible-light reflective film.

In another aspect, the present disclosure provides for a method that includes depositing an electrically conductive metal on a major surface of a film, the film having: alternating layers of a first polymeric material and a second polymeric material, each having a different index of refraction, and where at least one of the first and second polymeric materials includes a polydiorganosiloxane polyoxamide block copolymer; and patterning the electrically conductive metal to form a circuit.

The above summary is not intended to describe each disclosed embodiment or every implementation of the present disclosure. The figures and the detailed description below more particularly exemplify illustrative embodiments.

### BRIEF DESCRIPTION OF THE DRAWINGS

Throughout the specification reference is made to the appended drawings, where like reference numerals designate like elements, and wherein:

FIG. 1A shows a perspective view of a flexible circuit on reflective substrate; and

FIG. 1B shows a cross-sectional schematic through section A-A′ of FIG. 1A.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

The present disclosure describes materials and methods for creating electrical circuits on a non-conductive multilayer reflector substrate that can withstand reflow temperatures with low temperature solder pastes, without creating distortions in the reflective substrate. Electronic circuits can be fabricated on a variety of non-electrically conductive substrates, such as polymer films, plates, and composite circuit boards. For some applications, it may be particularly desirable to fabricate circuits on highly reflective substrates.

A non-metallic polymeric multilayer interference mirror such as 3M Enhanced Specular Reflector (ESR) can be used as the surface supporting an electrical circuit without shorting the conductors. However, the ESR film is typically applied after the circuit is fabricated, to avoid solder reflow temperatures that can damage the ESR film. Damage to the ESR film can occur at temperatures as low as about 130° C., generally much lower than solder reflow temperatures. In addition, cutting and applying ESR film as a secondary operation can add significant cost to a circuit assembly.

In the following description, reference is made to the accompanying drawings that forms a part hereof and in which are shown by way of illustration. It is to be understood that other embodiments are contemplated and may be made without departing from the scope or spirit of the present disclosure. The following detailed description, therefore, is not to be taken in a limiting sense.

All scientific and technical terms used herein have meanings commonly used in the art unless otherwise specified. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “lower,” “upper,” “beneath,” “below,” “above,” and “on top,” if used herein, are utilized for ease of description to describe spatial relationships of an element(s) to another. Such spatially related terms encompass different orientations of the device in use or operation in addition to the particular orientations depicted in the figures and described herein. For example, if an object depicted in the figures is turned over or flipped over, portions previously described as below or beneath other elements would then be above those other elements.

As used herein, when an element, component or layer for example is described as forming a “coincident interface” with, or being “on” “connected to,” “coupled with” or “in contact with” another element, component or layer, it can be directly on, directly connected to, directly coupled with, in direct contact with, or intervening elements, components or layers may be on, connected, coupled or in contact with the particular element, component or layer, for example. When an element, component or layer for example is referred to as being “directly on,” “directly connected to,” “directly coupled with,” or “directly in contact with” another element, there are no intervening elements, components or layers for example.

As used herein, “have”, “having”, “include”, “including”, “comprise”, “comprising” or the like are used in their open ended sense, and generally mean “including, but not limited to.” It will be understood that the terms “consisting of” and “consisting essentially of” are subsumed in the term “comprising,” and the like.

The present disclosure provides a technique of fabricating flexible electronic circuits directly onto a non-metallic polymeric multilayer interference mirror film (i.e., a visible-light reflective film) by fabricating novel multilayer optical films using materials that can withstand reflow temperatures which can be approximately 135° C. for a number of low temperature solder pastes. Representative solder paste examples include alloys of bismuth and tin in a ratio of approximately 58/42 which has a reflow temperature of 138° C., as supplied by Nordson EFD Corporation, Westlake Ohio, and also available from Indium Corporation of America, Utica, N.Y. In some cases, the novel multilayer optical films can withstand reflow temperatures that are not greater than 150° C., that can include several lead-free solder pastes such as, for example, Sn/In in a ratio of 52/48 (reflow 131° C.); Sn/In in a ratio of 58/42 (reflow 145° C.); In/Ga in a ratio of 99.3/0.7 (reflow 150° C.); In/Bi in a ratio of 95/5 (reflow 150° C.); Bi/Sn/Ag in a ratio of 57/42/1 (reflow 140° C.); and In/Ag in a ratio of 97/3 (reflow 143° C.); and others available from Indium Corporation of America, Utica, N.Y.

In one particular embodiment, the technique includes the use of a novel reflective mirror film based on silicone polyoxamide polymers or copolymers, which can retain reflectivity at these temperatures without damage to reflection or other film properties, conditions necessary for flexible circuit production on reflective substrates. The silicone polyoxamide polymers or copolymers include films such as those described in, for example, U.S. Pat. No. 7,501,184 entitled POLYDIORGANOSILOXANE POLYOXAMIDE COPOLYMERS; U.S. Pat. No. 7,820,297 entitled MULTILAYER FILMS INCLUDING THERMOPLASTIC SILICONE BLOCK COPOLYMERS; and U.S. Pat. No. 8,067,094 entitled FILMS INCLUDING THERMOPLASTIC SILICONE BLOCK COPOLYMERS.

In the electronics industry, LED circuits with reflective surfaces can serve as efficient light engines in a broad variety of LCD display applications from handheld and mobile devices to laptops, monitors, TVs and luminaires. By making light engines more efficient, manufacturers can increase system efficiency, reduce cost and improve brightness. In lighting systems for general illumination, combining electronic circuit and reflector can reduce part count and can also improve efficiency. Additional applications of the flexible circuits on reflective substrates can include, for example, solar energy and other sensor applications, as the present invention enables a sheet that can provide both reflective and electrical function in a single film.

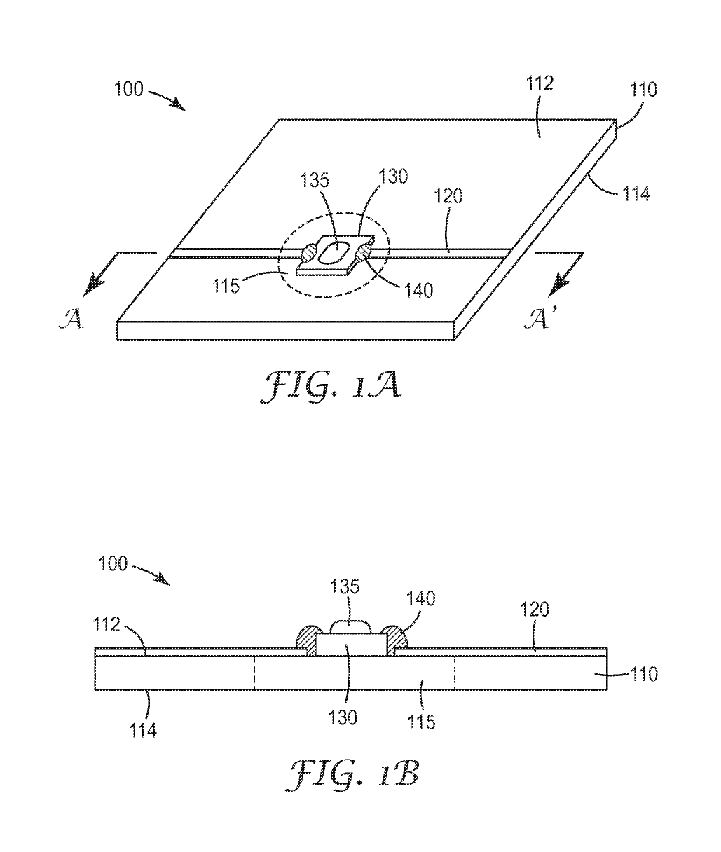

FIG. 1A shows a perspective view of a flexible circuit on reflective substrate 100, according to one aspect of the disclosure. Flexible circuit on reflective substrate 100 includes a polymeric multilayer interference reflector 110 having a first major surface 112 and an opposing second major surface 114. An electrically conductive metal 120 is disposed in a circuit pattern (here, represented by a break in the electrically conductive metal 120) on the first major surface 112. An electrical component 130, for example including an LED 135, is electrically connected to the electrically conductive metal 120 using solder joint 140. A locally heated region 115 within the reflective substrate 100 results from soldering the connection at the solder joint 140, and in some cases can extend throughout the entire polymeric multilayer interference reflector 110, for example during a reflow soldering process.

FIG. 1B shows a cross-sectional schematic through section A-A′ of FIG. 1A, according to one aspect of the disclosure. In FIG. 1B, the cross-section shows the electrically conductive metal 120 of the circuit pattern deposited directly on the first major surface 112 of the polymeric multilayer interference reflector 110. In some cases, a tie layer (not shown) may be deposited on the first major surface 112 of the polymeric interference reflector 110 to aid adhesion of the electrically conductive metal 120, as described elsewhere. In some cases, an adhesive layer (not shown) may be disposed between the electrically conductive metal 120 and the first major surface 112 of the polymeric interference reflector 110, to adhere the two together, as described elsewhere.

The locally heated region 115 generally extends through the thickness of the polymeric multilayer interference reflector 110, and can result in distortions of the tens- to hundreds- of alternating polymeric layers that comprise the polymeric multilayer interference reflector 110, which can lead to a decrease in reflectivity, particularly specular reflectivity. The present disclosure relates to thermally resistant materials making up the polymeric multilayer interference reflector 110, such that for the solder reflow temperatures contemplated, degradation of performance does not occur.

The process steps for fabricating flexible circuits on reflective substrates include steps known in the art used to make so-called “adhesively attached flex circuits” and/or “adhesiveless flex circuits”. In some cases, for example, adhesively attached flex circuits can include a conductive metal trace having an adhesive backing that can collectively be patterned and adhesively attached to a major surface of the reflective substrate, as known to those of skill in the art.

In some cases, both adhesively attached flex circuits and adhesiveless flex circuits can include an optional conductive adhesion-promoting “tie” layer deposited onto the reflective substrate by using one of a variety of techniques including, for example, sputtering, vapor deposition, plasma deposition, or e-beam evaporation. In some cases, the “tie” layer can comprise a readily deposited metal that adheres well to the outer surface of the reflective substrate such as, for example, chromium, nickel-chromium, and others, as known to those of skill in the art. In one particular embodiment, the “tie” layer can be deposited at a thickness ranging from about 5 nm to about 30 nm, or from about 5 nm to about 20 nm, or from about 10 nm to about 15 nm.

In some cases, adhesiveless flex circuits can be preferred, and can include a metal “seed” layer that can then be optionally deposited on the “tie” layer by any similar technique; the “seed” layer typically can be used as a conductive base for plating the conductors of the flexible circuit, and can be the same metal or a different metal as the flexible circuit. In one particular embodiment, the “seed” layer can be deposited at a thickness ranging from about 50 nm to about 500 nm, or from about 50 nm to about 200 nm, or from about 100 nm to about 150 nm. In some cases, seed layers can be deposited to a thickness as low as 15 nm, and still result in acceptable plating. In some cases, the electrically conductive metal of the flexible circuit and/or the “seed” layer can include copper, silver, aluminum, tin, gold, or an alloy or combination thereof. In some cases, the electrically conductive metal can include a laminate of at least two metals, for example, silver and copper.

The electrically conductive metal can be deposited by plating at least one metal on the adhesion promoting “tie” layer and/or the “seed” layer by any known technique, for example by using electroplating or electroless plating. In one particular embodiment, the electrically conductive metal can be deposited at a thickness ranging from about 2 microns to about 50 microns, or from about 2 microns to about 25 microns, or from about 10 microns to about 20 microns.

The electrically conductive metal can then be patterned to form a circuit by any of the patterning techniques commonly employed, such as including the steps of applying a photoresist, patterning the photoresist, etching the electrically conductive metal, and removing the photoresist. At least one electronic component can then be soldered to the electrically conductive metal circuit on the reflective substrate.

### EXAMPLES

### Comparative Example

Several attempts were made to create electronic circuits on an ESR film polymeric reflector, available from 3M Company. The process steps were similar to those used to make so-called “adhesiveless flex circuits”, e.g. copper on a polymer substrate created by plating metal on the polymer substrate instead of through adhesive lamination of a metal film. The first step in the process was to sputter coat a conductive “tie” layer onto the ESR film using a metal and process that will bond to the substrate polymer, as known to one of skill in the art. Conductive ESR mirror films were fabricated by sputter coating approximately 10 nm of chromium onto the surface, then sputtering copper to about 100 nm thickness, and finally plating with copper to about 12-20 microns thickness. The resulting “optical flex” was then patterned and etched using a conventional circuit pattern process. The resulting circuits retained their mirror surface, which supports the patterned conductive traces.

These ESR substrate circuits were then tested for solder-ability, and it was discovered that hand soldering was possible with a solder iron set to approximately 550° F. (288° C.) using tin/lead solder in a 63/37 ratio. However, testing with higher temperature lead-free solder such as a tin/silver/copper solder in a 96.5/3/0.5 ratio was more difficult, since soldering was only possible using fine point soldering irons and only when the tip of the iron only contacted the copper plating. Any contact with the ESR film substrate resulted in an instant hole or defect.

Tests using low temperature tin/bismuth solder paste in a reflow process resulted in the mirror surface wrinkling severely, reducing the reflective properties. Several attempts were made to modify the process, but the ESR film wrinkled about 10 degrees C. lower than the reflow temperature of the solder paste which was 138° C. The solder paste used was an alloy of bismuth and tin (Bi/Sn) solder paste composition having a ratio of 58/42, with a reflow temperature of 138° C. (available from Nordson EFD Corporation, Westlake Ohio)

### Example 1

A silicone polyoxamide-based mirror having 275 alternating layers of polyethylene terephthalate (PET) as the high index material and the skin, and polydiorganosiloxane polyoxamide thermo Plastic silicone elastomer as the low index material, prepared according to the procedures described in U.S. Pat. No. 7,820,297 was used as the visible-light reflective film. A “tie” layer of about 5 nm of chromium was deposited on the silicone polyoxamide-based mirror, and then a “seed” layer of about 250 nm of copper was deposited on the “tie” layer, both using a batch coater with an E-beam evaporation source. Copper was then plated to a thickness of approximately 18 to 20 microns of copper using an electroplating process. An LED circuit was patterned onto the copper surface and the film. The circuit was approximately 230 mm long having two power buses approximately 1 mm wide and spaced approximately 10 mm apart connecting an LED circuit running between the buses. The film was etched in a ferric chloride bath to remove unpatterned copper, and then in a mixture of potassium permanganate and potassium hydroxide to remove the chrome layer and reveal a flexible circuit on the reflective substrate, suitable for attachment of an LED.

The flexible circuit on the reflective substrate was then laminated to an aluminum sheet using TC 2810 thermally conductive epoxy, available from 3M Company. A Bi/Sn solder paste composition having a ratio of 58/42, with a reflow temperature of 138° C. (available from Nordson EFD Corporation, Westlake Ohio) was deposited on the component pads of the circuit. The LED circuit was populated with 6 Osram Oslon LEDs in series. The LEDs were placed in the paste and heated to a temperature of 150° C. The circuit was cooled and tested, and the LEDs were able to be powered and illuminated. The surface of the mirror film appeared to be un-damaged and still showed specular reflectivity.

Following are a list of embodiments of the present disclosure.

Item 1 is a flexible circuit, comprising: a visible-light reflective film having alternating layers of a first polymeric material and a second polymeric material, each having a different index of refraction, and where at least one of the first and second polymeric materials comprises a polydiorganosiloxane polyoxamide block copolymer; and an electrically conductive metal disposed in a circuit pattern on the visible-light reflective film.

Item 2 is the flexible circuit of item 1, wherein a difference in the index of refraction between the first and second polymeric materials is greater than about 0.05.

Item 3 is the flexible circuit of item 1 or item 2, wherein each of the first and second polymeric material comprises silicone polyoxamide block copolymers.

Item 4 is the flexible circuit of item 1 to item 3, wherein at least one of the first and second polymeric materials comprise polyethylene terephthalate (PET), polyethylene naphthalate (PEN), PET/silicone polyoxamide block copolymers, PEN/silicone polyoxamide block copolymers, PMMA/silicone polyoxamide block copolymers or combinations thereof.

Item 5 is the flexible circuit of item 1 to item 4, wherein the electrically conductive metal comprises copper, silver, aluminum, tin, gold, or an alloy or combination thereof. Item 6 is the flexible circuit of item 1 to item 5, wherein the electrically conductive metal comprises a laminate of at least two metals.

Item 7 is the flexible circuit of item 6, wherein the laminate of at least two metals comprises silver and copper.

Item 8 is the flexible circuit of item 1 to item 7, wherein the visible-light reflective film is electrically non-conductive.

Item 9 is the flexible circuit of item 1 to item 8, further comprising at least one electronic component soldered to the electrically conductive metal.

Item 10 is the flexible circuit of item 9, wherein the at least one electronic component comprises a light emitting diode (LED).

Item 11 is the flexible circuit of item 9 or item 10, wherein the solder is a low temperature solder having a melting point not greater than about 150 C.

Item 12 is the flexible circuit of item 9 to item 11, wherein the solder is a low temperature solder having a melting point not greater than about 138 C.

Item 13 is the flexible circuit of item 9 to item 12, wherein the solder comprises a mixture of tin and bismuth.

Item 14 is the flexible circuit of item 9 to item 13, wherein the visible-light reflective film surrounding the soldered electronic component is not visibly distorted.

Item 15 is the flexible circuit of item 1 to item 14, further comprising an adhesion promoting tie layer disposed between the visible-light reflective film and the electrically conductive metal.

Item 16 is the flexible circuit of claim 15, wherein the adhesion promoting tie layer comprises chromium.

Item 17 is the flexible circuit of item 1 to item 16, further comprising an adhesive disposed between the visible-light reflective film and the electrically conductive metal.

Item 18 is a method, comprising: depositing an electrically conductive metal on a major surface of a film, the film comprising: alternating layers of a first polymeric material and a second polymeric material, each having a different index of refraction, and where at least one of the first and second polymeric materials comprises a polydiorganosiloxane polyoxamide block copolymer; and patterning the electrically conductive metal to form a circuit.

Item 19 is the method of item 18, further comprising depositing an adhesion promoting tie layer on the major surface of the film prior to depositing the electrically conductive metal.

Item 20 is the method of item 19, wherein depositing the adhesion promoting tie layer comprises sputtering, vapor deposition, plasma deposition, or e-beam evaporation.

Item 21 is the method of item 18, wherein the electrically conductive metal comprises an adhesive layer that adheres the electrically conductive metal to the major surface of the film

Item 22 is the method of item 18 to item 21, wherein depositing an electrically conductive metal comprises plating at least one metal on the adhesion promoting tie layer.

Item 23 is the method of item 22, wherein plating comprises electroplating.

Item 24 is the method of item 18 to item 23, wherein patterning the electrically conductive metal comprises the steps of applying a photoresist, patterning the photoresist, etching the electrically conductive metal, and removing the photoresist.

Item 25 is the method of item 18 to item 24, further comprising soldering at least one electrical component to the circuit.

Unless otherwise indicated, all numbers expressing feature sizes, amounts, and physical properties used in the specification and claims are to be understood as being modified by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A flexible circuit, comprising:
a visible-light reflective film having alternating layers of a first polymeric material and a second polymeric material, each having a different index of refraction, and where at least one of the first and second polymeric materials comprises a polydiorganosiloxane polyoxamide block copolymer; and
an electrically conductive metal disposed in a circuit pattern on the visible-light reflective film.

2. The flexible circuit of claim 1, wherein a difference in the index of refraction between the first and second polymeric materials is greater than about 0.05.

3. The flexible circuit of claim 1, wherein each of the first and second polymeric material comprises silicone polyoxamide block copolymers.

4. The flexible circuit of claim 1, wherein at least one of the first and second polymeric materials comprise polyethylene terephthalate (PET), polyethylene naphthalate (PEN), PET/silicone polyoxamide block copolymers, PEN/silicone polyoxamide block copolymers, PMMA/silicone polyoxamide block copolymers or combinations thereof.

5. The flexible circuit of claim 1, wherein the electrically conductive metal comprises copper, silver, aluminum, tin, gold, or an alloy or combination thereof.

6. The flexible circuit of claim 1, wherein the electrically conductive metal comprises a laminate of at least two metals.

7. The flexible circuit of claim 6, wherein the laminate of at least two metals comprises silver and copper.

8. The flexible circuit of claim 1, wherein the visible-light reflective film is electrically non-conductive.

9. The flexible circuit of claim 1, further comprising at least one electronic component soldered to the electrically conductive metal.

10. The flexible circuit of claim 9, wherein the at least one electronic component comprises a light emitting diode (LED).

11. The flexible circuit of claim 9, wherein the solder is a low temperature solder having a melting point not greater than about 150 C.

12. The flexible circuit of claim 9, wherein the solder is a low temperature solder having a melting point not greater than about 138 C.

13. The flexible circuit of claim 12, wherein the solder comprises a mixture of tin and bismuth.

14. The flexible circuit of claim 9, wherein the visible-light reflective film surrounding the soldered electronic component is not visibly distorted.

15. The flexible circuit of claim 1, further comprising an adhesion promoting tie layer disposed between the visible-light reflective film and the electrically conductive metal.

16. The flexible circuit of claim 15, wherein the adhesion promoting tie layer comprises chromium.

17. The flexible circuit of claim 1, further comprising an adhesive disposed between the visible-light reflective film and the electrically conductive metal.

18. A method, comprising:
depositing an electrically conductive metal on a major surface of a film, the film comprising:
alternating layers of a first polymeric material and a second polymeric material, each having a different index of refraction, and where at least one of the first and second polymeric materials comprises a polydiorganosiloxane polyoxamide block copolymer; and
patterning the electrically conductive metal to form a circuit.

19. The method of claim 18, further comprising depositing an adhesion promoting tie layer on the major surface of the film prior to depositing the electrically conductive metal.

20. The method of claim 19, wherein depositing the adhesion promoting tie layer comprises sputtering, vapor deposition, plasma deposition, or e-beam evaporation.

21. The method of claim 18, wherein the electrically conductive metal comprises an adhesive layer that adheres the electrically conductive metal to the major surface of the film

22. The method of claim 18, wherein depositing the electrically conductive metal comprises plating at least one metal.

23. The method of claim 22, wherein plating comprises electroplating.

24. The method of claim 18, wherein patterning the electrically conductive metal comprises the steps of applying a photoresist, patterning the photoresist, etching the electrically conductive metal, and removing the photoresist.

25. The method of claim 18, further comprising soldering at least one electrical component to the circuit.
